(19) United States
(12) Patent Application Publication
(10) Pub. No.: US 2015/0029415 A1
(43) Pub. Date: Jan. 29, 2015

(54) TOUCH PANEL STRUCTURE, METHOD FOR FORMING THE SAME AND TOUCH DEVICE HAVING THE SAME

(71) Applicant: CANDO CORPORATION, Hsinchu County (TW)

(72) Inventors: CHUNG-CHI WANG, Hsinchu County (TW); YUN-WEN CHEN, Hsinchu County (TW)

(73) Assignee: CANDO CORPORATION, Hsinchu County (TW)

(21) Appl. No.: 14/257,811

(22) Filed: Apr. 21, 2014

(30) Foreign Application Priority Data
Jul. 24, 2013 (TW) 102126428

(51) Int. Cl. G06F 3/01; C23C 14/10; C23C 14/06; B05D 7/00; B05D 5/06

(52) U.S. Cl. CPC G06F 3/01; B05D 7/56; B05D 5/06; C23C 14/0652; C23C 14/10
USPC 349/12; 427/162

(57) ABSTRACT

The present invention discloses a touch panel structure, a method for forming the same and a touch device having the same. A touch panel structure of the present invention comprises a substrate, a color layer, an inorganic layer, and a photoresist layer. The color layer is disposed on a surface of the substrate. The inorganic layer is disposed on a surface of the color layer which is opposite to the substrate. The photoresist layer is disposed on a surface of the inorganic layer which is opposite to the substrate, wherein the color layer and the photoresist layer have different surface tensions. For electronic products that rely on the Colorful OGS (One Glass Solution) technology, by providing an inorganic layer between the color layer and the photoresist layer, problems related to different surface tensions when the layers are stacked during the manufacturing process of a touch panel can be solved.

### CROSS-REFERENCE TO RELATED APPLICATIONS

This non-provisional application claims priority under 35 U.S.C. §119(a) on Patent Application No. 102126428 filed in Taiwan, R.O.C. on Jul. 24, 2013, the entire contents of which are hereby incorporated by reference.

### BACKGROUND OF THE INVENTION

1. Field of the Invention

The present invention relates to a touch panel structure and a method for forming the same. More particularly, the present invention relates to a touch panel structure which improves problems related to different surface tensions between stacked layers; also, the present invention relates to a method for forming such a touch panel and to a touch device having the same.

2. Description of the Prior Art

As touch panel technology keeps advancing while consumer electronics gain increasing popularity in recent years, touchscreens are even more widely used in many products. Touchscreens used to be adopted in particular product categories, but now, a wide range of electronic product manufacturers have adopted touchscreen as a fundamental part of a product. Touchscreens have become a popular application that has a fast growing market.

FIGS. 1A and 1B are first and second schematic views showing part of an existing touch panel structure. As shown in FIGS. 1A and 1B, an existing touch panel structure 1, which is manufactured using Colorful One Glass Solution (Colorful OGS) technology, mainly comprises a substrate 11 and a color layer 12 disposed on the substrate 11 (the color layer 12 may be configured to comprise one or more layers depending on the needs). Moreover, there is generally at least one photoresist layer disposed on the color layer 12 to produce an “shielding” effect as needed. The color layer 12 may be composed of ink, while the photoresist layer is composed of a different material (i.e., non-ink). Since different materials have different surface tensions, this difference in surface tension may easily lead to a problem called “coating ununiformity” (as the photoresist layer 13 showed in FIG. 1B) on the color layer 12. To be more specific, when the layers of a touch panel are stacked, there is a significant difference in surface tension between the color layer 12, which is composed of ink, and the photoresist layer 13 (since the color layer 12 has a larger contact angle while the photoresist layer 13 has a smaller one). As a result, the coating of the upper layer (i.e., the photoresist layer 13) cannot be uniformly applied onto the lower layer (i.e., the color layer 12) during the manufacturing process.

It is thus necessary to address the aforesaid problem of coating ununinformity that occurs during the existing manufacturing process of a touch panel. Hence, there exists a need in the industry whose products rely on the Colorful OGS technology, for a touch panel structure that effectively solves the problem related to different surface tensions when the layers are stacked during the manufacturing process. Accordingly, a method for forming such a touch panel structure and a touch device comprising the touch panel structure are also needed.

### SUMMARY OF THE INVENTION

In view of the above drawbacks of the prior art technique, it is an aspect of the present invention to provide a touch panel structure, a method for forming the same and a touch device having the same, so that for electronic products that rely on the Colorful OGS technology, problems related to different surface tensions when the layers are stacked during the manufacturing process of a touch panel can be solved.

According to an aspect of the present invention, there is provided a touch panel structure comprising a substrate, a color layer, an inorganic layer, and a photoresist layer. The color layer is disposed on a surface of the substrate. The inorganic layer is disposed on a surface of the color layer which is opposite to the substrate. The photoresist layer is disposed on a surface of the inorganic layer which is opposite to the substrate, wherein the color layer and the photoresist layer have different surface tensions.

According to an aspect of the present invention, there is provided a method for forming a touch panel structure comprising: providing a substrate; providing a color layer on a surface of the substrate; providing an inorganic layer on a surface of the color layer which is opposite to the substrate; and providing a photoresist layer on a surface of the inorganic layer which is opposite to the color layer, wherein the color layer and the photoresist layer have different surface tensions.

According to an aspect of the present invention, there is provided a touch device comprising a touch panel structure, wherein the touch panel structure comprises a substrate, a color layer, an inorganic layer, and a photoresist layer. The color layer is disposed on a surface of the substrate. The inorganic layer is disposed on a surface of the color layer which is opposite to the substrate. The photoresist layer is disposed on a surface of the inorganic layer which is opposite to the substrate, wherein the color layer and the photoresist layer have different surface tensions.

The aforementioned aspects and other aspects of the present invention will be better understood with reference to the following exemplary embodiments and drawings.

### BRIEF DESCRIPTION OF THE DRAWINGS

FIG. 1A is a first schematic view showing part of an existing touch panel structure.

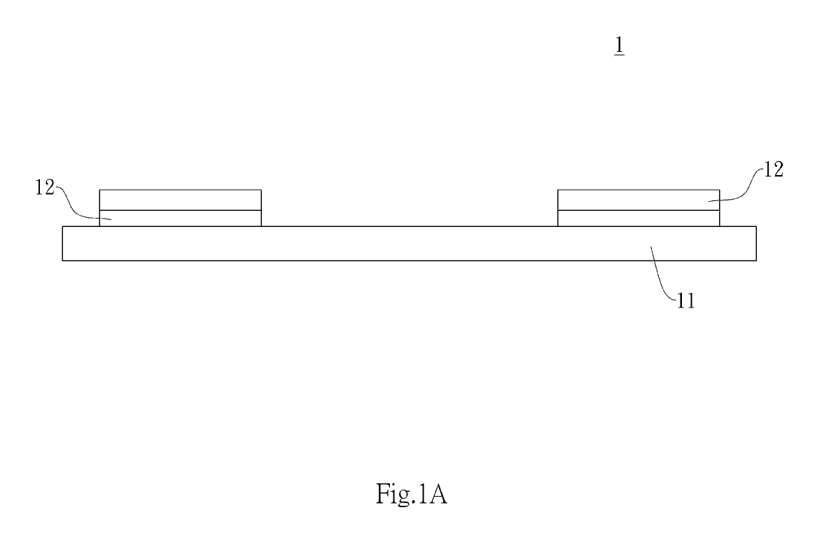

FIG. 1B is a second schematic view showing part of an existing touch panel structure.

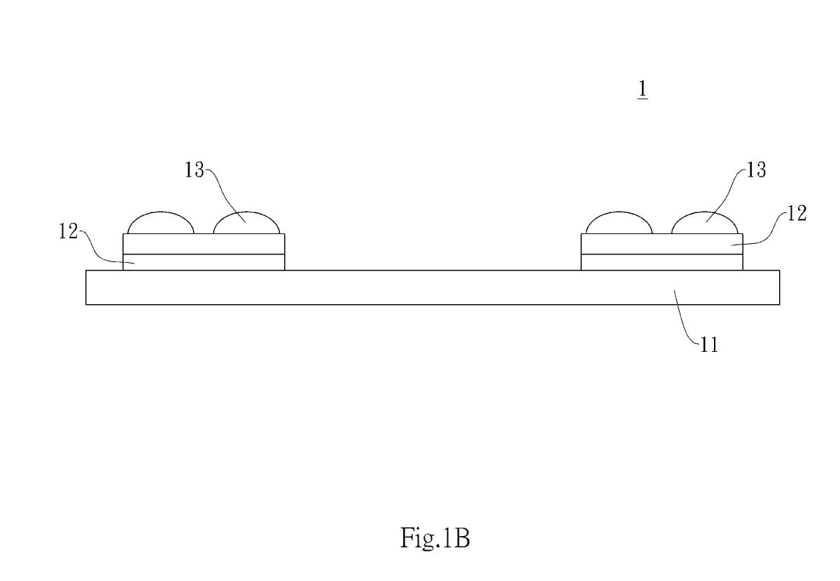

FIG. 2A is a first cross-sectional view of a touch panel structure according to a first embodiment of the present invention.

FIG. 2B is a second cross-sectional view of a touch panel structure according to a first embodiment of the present invention.

FIG. 3 is a cross-sectional view of a touch panel structure according to a second embodiment of the present invention.

FIG. 4 is a schematic view showing part of a touch panel structure in a product example according to an embodiment of the present invention.

FIG. 5 is a flow chart showing a method for forming a touch panel structure according to an embodiment of the present invention.

### DETAILED DESCRIPTION OF THE PREFERRED EMBODIMENTS

The present invention will be fully described by way of preferred embodiments and appended drawings to facilitate the understanding of the technical features, contents and advantages of the present invention. It will be understood that the appended drawings are merely schematic representations and may not be illustrated according to actual scale and precise arrangement of the implemented invention. Therefore, the present invention shall not be construed based on the scale and arrangement illustrated on the appended drawings, and the embodiments and appended drawings are not intended to limit the scope of protection of the present invention.

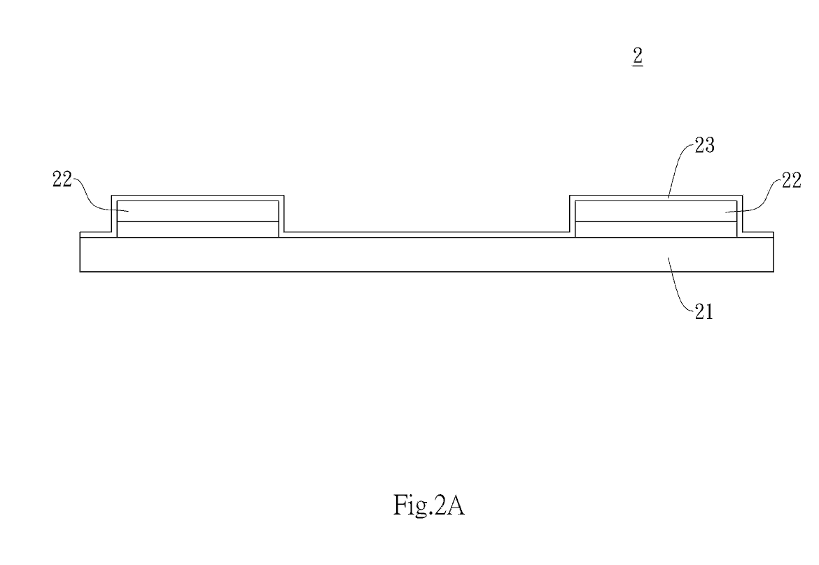

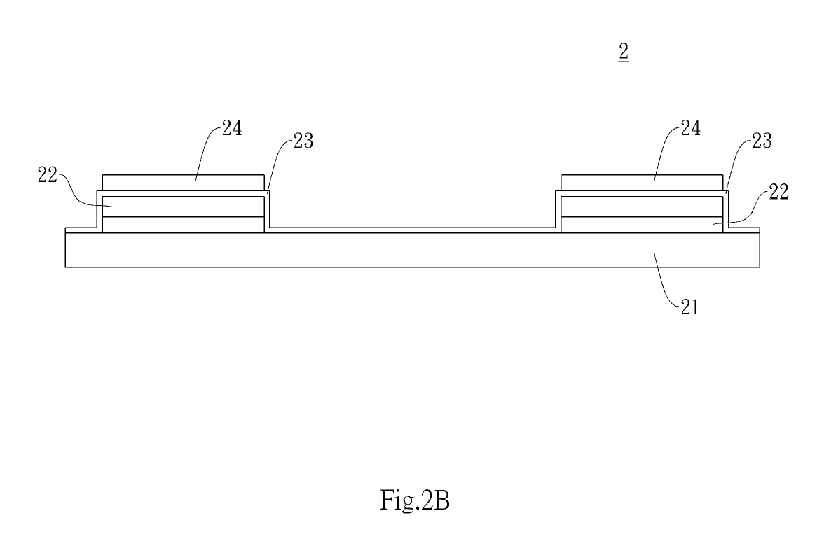

FIG. 2A is a first cross-sectional view and FIG. 2B a second cross-sectional view of a touch panel structure according to a first embodiment of the present invention; the two figures illustrate a basic construction of a touch panel structure according to the embodiment of present invention. As the figures show, a touch panel structure 2 of the embodiment of present invention mainly comprises a substrate 21, a color layer 22, an inorganic layer 23, and a photoresist layer 24. The color layer 22 may be disposed on a surface of the substrate 21, and preferably, the color layer 22 may have a transmittance of more than 1%. Preferably, the inorganic layer 23 may be disposed on a surface of the color layer 22 which is opposite to the substrate 21 (the inorganic layer 23 may also be disposed on a surface of the substrate 21 where no color layer 22 is disposed). The photoresist layer 24 may be disposed on a surface of the inorganic layer 23 which is opposite to the color layer 22. In this embodiment, the color layer 22 may comprise ink, and the photoresist layer 24 may be a black matrix resist. In real practice, however, the materials used for forming the color layer and the photoresist layer are not limited to those as described above.

Further, in an embodiment of the present invention, the inorganic layer 23 of the touch panel structure 2 may preferably comprise a ceramic material. In real practice, the inorganic layer 23 may be formed on a surface of the color layer 22 using a physical vapor deposition (PVD) process by sputtering, wherein the ceramic material for the inorganic layer 23 may be silicon oxide (SiOₓ), silicon nitride (SiNₓ) or others. In real practice, however, the materials used for forming the inorganic layer 23 are not limited to those as described above.

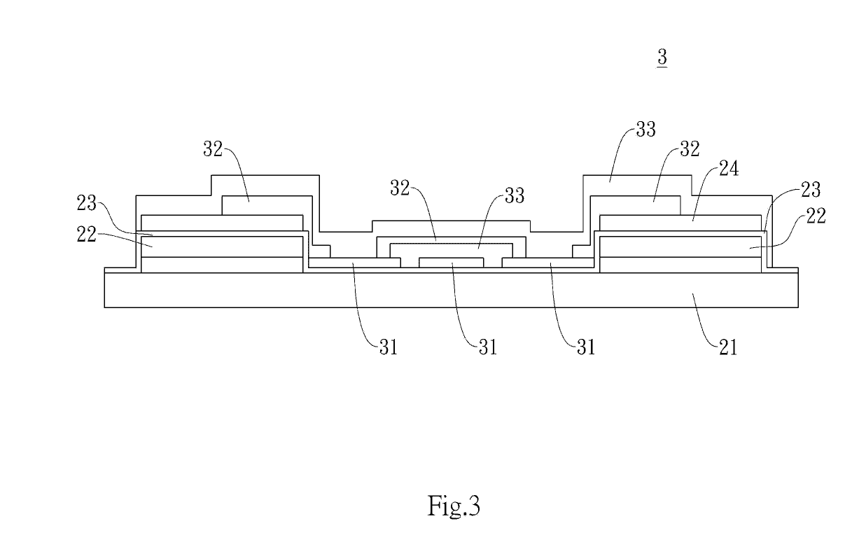

FIG. 3 is a cross-sectional view of a touch panel structure according to a second embodiment of the present invention, illustrating another basic construction of the touch panel structure according to the embodiment of present invention. As FIG. 3 shows, the touch panel structure in the second embodiment is basically similar to that in the first embodiment.

Compared with the touch panel structure 2 in the first embodiment, however, the touch panel structure 3 in this embodiment further comprises a layer of indium tin oxide (ITO) pattern/bridge 31, a metal layer 32, and other photoresist layers 33. In this embodiment, the inorganic layer 23 is also exactly disposed between the color layer 22, which comprises ink, and the photoresist layer 24. A person having ordinarily knowledge in the art shall understand that the touch panel structure in the second embodiment is exemplary and is not intended to limit the present invention.

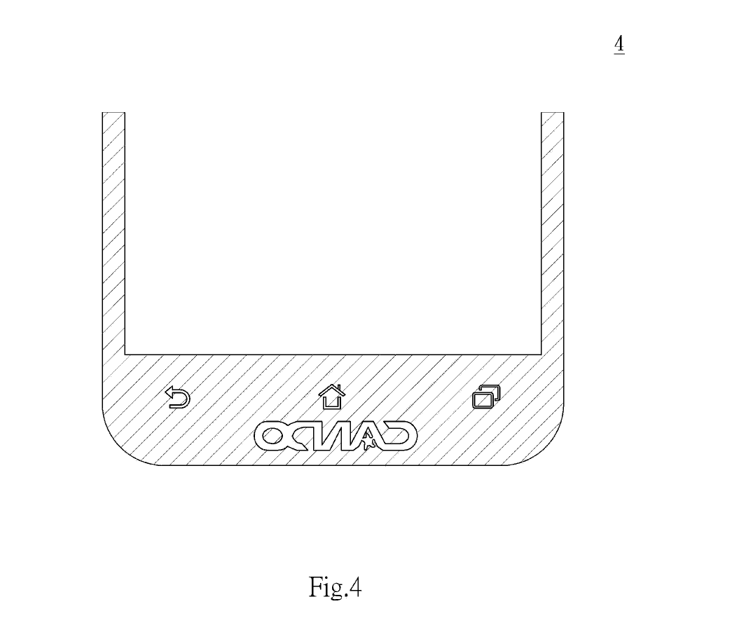

FIG. 4 is a schematic view showing part of a touch panel structure in a product example according to an embodiment of the present invention; this figure illustrates a touch device according to the embodiment of present invention. A touch panel structure 2 or 3 according to the embodiment of present invention may be provided in a touch device 4 shown in FIG. 4. As described above, the touch panel structure 2 or 3 may comprise a substrate 21, a color layer 22, an inorganic layer 23, and a photoresist layer 24, wherein the inorganic layer 23 is disposed between the color layer 22, which comprises ink, and the photoresist layer 24. The touch device 4 may be, for example, a touchscreen monitor, a portable mobile device with a touchscreen, or an electronic appliance incorporating touch technology, but is not limited to these examples.

It should be noted that a person having ordinarily knowledge in the art shall understand that the aforementioned embodiments regarding the transmittance of the color layer 22 and the materials of the color layer 22, the photoresist layer 24, and the inorganic layer 23, are exemplary and are not intended to limit the present invention. Any touch panel structure made without departing from the spirit and scope of the present invention falls within the scope of the present invention.

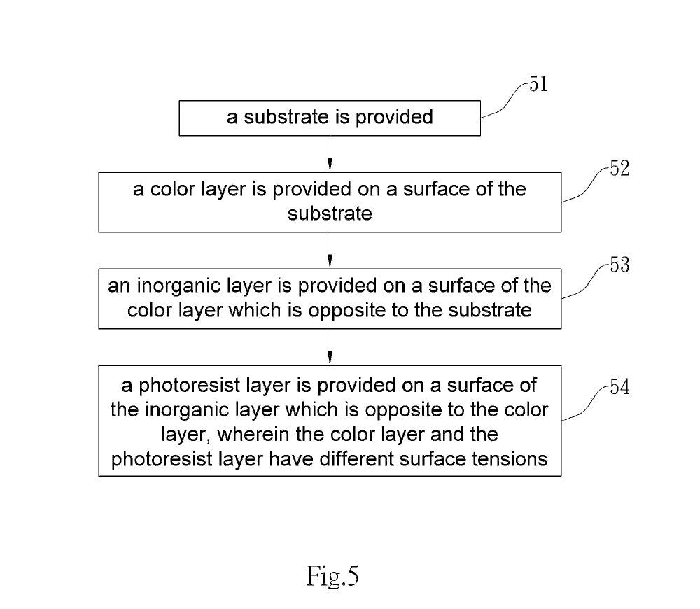

FIG. 5 is a flow chart showing a method for forming a touch panel structure according to an embodiment of the present invention. As FIG. 5 shows, a method for forming a touch panel structure according to the embodiment of present invention may comprise the following steps. In step 51, a substrate is provided, wherein the substrate may be a cover lens. In step 52, a color layer is provided on a surface of the substrate. In an embodiment of the present invention, ink is used to form the color layer provided on the surface of the substrate. In step 53, an inorganic layer is provided on a surface of the color layer which is opposite to the substrate. In an embodiment of the present invention, a ceramic material is used to form the inorganic layer on the surface of the substrate with a PVD process by sputtering. In step 54, a photoresist layer is provided on a surface of the inorganic layer which is opposite to the color layer, wherein the color layer and the photoresist layer have different surface tensions.

In sum, the present invention provides a touch panel structure, a method for forming the same and a touch device having the same. The present invention is advantageous in at least the following aspect: For electronic products that rely on the Colorful OGS technology, the coating shrinkage problem that occurs to the photoresist layer during the manufacturing process due to different surface tensions of the materials used for forming the color layer and the photoresist layer can be solved. Improved leveling can thus be achieved for photoresist coating.

The present invention, which includes a touch panel structure, a method for forming the same and a touch device having the same, has been described above by way of preferred embodiments with reference to the accompanying drawings. All of the advantageous features disclosed in this specification may be combined in any combination. Each feature disclosed in this specification may be replaced by an alternative feature serving the same, equivalent, or similar purpose. Thus, except for those particularly distinctive features, each feature disclosed is only an example of a generic series of equivalent or similar features. Given the above description of preferred embodiments, those skilled in the art would understand that the present invention features several aspects of novelty and inventive step over the prior art and is industrially applicable. Various modifications and substitutions may be made by those skilled in the art without departing from the spirit and scope of the present invention.

What is claimed is:

1. A touch panel structure, comprising:
a substrate;
a color layer disposed on the substrate;
an inorganic layer disposed on a surface of the color layer which is opposite to the substrate; and
a photoresist layer disposed on a surface of the inorganic layer which is opposite to the color layer,
wherein the color layer and the photoresist layer have different surface tensions.

2. The touch panel structure according to claim 1, wherein the color layer comprises ink.

3. The touch panel structure according to claim 1, wherein the inorganic layer comprises a ceramic material.

4. The touch panel structure according to claim 3, wherein the ceramic material comprises silicon oxide (SiOₓ) or silicon nitride (SiNₓ).

5. A method for forming a touch panel structure, comprising:
providing a substrate;
providing a color layer on the substrate;
providing an inorganic layer on a surface of the color layer which is opposite to the substrate; and
providing a photoresist layer on a surface of the inorganic layer which is opposite to the color layer,
wherein the color layer and the photoresist layer have different surface tensions.

6. The method according to claim 5, wherein the color layer comprises ink.

7. The method according to claim 5, wherein the inorganic layer comprises a ceramic material.

8. The method according to claim 7, wherein the ceramic material comprises silicon oxide (SiOₓ) or silicon nitride (SiNₓ).

9. A touch device comprising a touch panel structure, the touch panel structure comprising:
a substrate;
a color layer disposed on the substrate;
an inorganic layer disposed on a surface of the color layer which is opposite to the substrate; and
a photoresist layer disposed on a surface of the inorganic layer which is opposite to the color layer,
wherein the color layer and the photoresist layer have different surface tensions.

10. The touch device according to claim 9, wherein the inorganic layer comprises a ceramic material.
